(19) United States
(12) Patent Application Publication
(10) Pub. No.: US 2025/0191951 A1
(43) Pub. Date: Jun. 12, 2025

(54) CARRIAGE DRIVING SYSTEM AND METHOD

(71) Applicant: SEMES CO., LTD., Cheonan-si (KR)

(72) Inventors: Dasom KIM, Hwaseong-si (KR); Taeuk PARK, Nam-gu (KR)

(21) Appl. No.: 18/975,387

(22) Filed: Dec. 10, 2024

(30) Foreign Application Priority Data
Dec. 12, 2023 (KR) 10-2023-0180126

(51) Int. Cl. H01L 21/677; H01L 21/67

(52) U.S. Cl. CPC H01L 21/67766; H01L 21/67265; H01L 21/6773

(57) ABSTRACT

The present invention relates to a carriage driving system including: a carriage configured to travel along a driving rail of a track; a driving direction detection unit formed on a part of the carriage and configured to detect a driving direction or surrounding objects; and a vehicle control unit formed on another part of the carriage and configured to control driving of the carriage, wherein the driving direction detection unit comprises at least one serial data generation unit configured to generate serial data so as to allow the vehicle control unit to check in real time whether the driving direction detection unit is operating normally.

### CROSS-REFERENCE TO RELATED APPLICATION(S)

This application claims the benefit under 35 USC § 119 (a) of Korean Patent Application No. 10-2023-0180126, filed on Dec. 12, 2023, in the Korean Intellectual Property Office, the entire disclosure of which is incorporated herein by reference for all purposes.

### BACKGROUND

### 1. Field

The following description relates to a carriage driving system and method, and more specifically, to a carriage driving system and method that enables the detection of abnormal conditions in a carriage in advance, before a collision occurs between carriages, allowing for prompt follow-up actions.

### 2. Description of Related Art

Semiconductor products are manufactured through hundreds of processes, and during the semiconductor manufacturing process, hundreds of thousands of logistics movements occur. To prevent contamination, damage to semiconductor materials, and delivery accidents during this logistics transportation process, semiconductor fabrication lines utilize Overhead Hoist Transport (OHT) as an automated transportation system.

The OHT is a system that automates transportation between numerous semiconductor processes, and is responsible for transporting wafers contained in Front Opening Unified Pods (FOUPs) to the appropriate manufacturing equipment for each production process along ceiling-mounted tracks.

The OHT, which allows carriages to travel along driving rails, may receive power wirelessly through power supply cables installed along the rails. Additionally, the OHT may be operated and managed by a higher-level server, which communicates wirelessly with each carriage to receive feedback information such as power status and operation status.

In conventional carriages, various types of sensors, such as detection switches, cameras, distance sensors, ultrasonic sensors, rail detection sensors, and surrounding object detection sensors, are installed in a driving direction detection unit to detect driving directions, such as left turns, driving straight, and right turns, or to prevent collisions. A vehicle control unit, which communicates with the driving direction detection unit, may also be installed to control the driving of the carriage.

### SUMMARY

Conventionally, however, when the driving direction detection unit erroneously operates under abnormal conditions or when communication issues occur, the vehicle control unit may also continue driving in an abnormal state, frequently leading to collisions with other carriages on the rail. When such collisions occur, significant losses may result, such as damage to the semiconductor materials being loaded or damage to the carriages themselves. Additionally, identifying the cause of the issue and taking follow-up actions, such as repair or replacement of parts, require significant time and manpower, significantly reducing productivity.

The present invention has been devised to address various problems including the aforementioned problems of the related art and an object of the present invention is to provide a carriage driving system and method in which a serial data generation unit is installed in a driving direction detection unit, enabling a vehicle control unit to monitor abnormalities in the driving direction detection unit in real-time, thereby detecting an abnormal condition of a carriage in advance, before a collision occurs, and allowing timely follow-up actions to be taken. However, this object is merely illustrative, and the scope of the present invention is not limited thereto.

According to an embodiment of the present invention, a carriage driving system includes: a carriage configured to travel along a driving rail of a track; a driving direction detection unit formed on a part of the carriage and configured to detect a driving direction or surrounding objects; and a vehicle control unit formed on another part of the carriage and configured to control driving of the carriage, wherein the driving direction detection unit comprises at least one serial data generation unit configured to generate serial data so as to allow the vehicle control unit to check in real time whether the driving direction detection unit is operating normally.

The driving direction detection unit may include an area detection command data receiving unit configured to receive area detection command data or command input/output data from the vehicle control unit and a first serial data generation unit configured to generate first serial data and integrate the area detection command data or command input/output data with the first serial data.

The vehicle control unit may include an area detection command data transmission unit configured to transmit the area detection command data or command input/output data to the area detection command data receiving unit and a first integrated data receiving unit configured to receive first integrated data in which the area detection command data or command input/output data and the first serial data are integrated or sequentially linked.

The first integrated data may be a data set in which first serial data, located at one or more predetermined positions among the front, middle, or rear position of the entire data set, is integrated with command data located at the remaining positions.

The vehicle control unit may further include a synchronization determination unit configured to periodically determine real-time synchronization under the same conditions between the area detection command data or command input/output data and the first serial data of the first integrated data.

The vehicle control unit may further include a consistency determination unit configured to periodically determine the consistency between the first serial data of the first integrated data, determined as synchronized, and first serial data generated by the vehicle control unit or an external server.

The vehicle control unit may further include an error signal output unit configured to output an error signal to stop driving or enable taking follow-up actions when synchronization or consistency is determined to be inadequate.

The driving direction detection unit may include a detection level data transmission unit configured to transmit detection level data detected by a sensor to the vehicle control unit and a second serial data generation unit configured to generate second serial data and integrate the detection level data with the second serial data.

The vehicle control unit may include a second integrated data receiving unit configured to receive second integrated data in which the detection level data and the second serial data are integrated or sequentially linked.

The second integrated data may be a data set in which second serial data, located at one or more predetermined positions among the front, middle, or rear position of the entire data set, is integrated with detection level data located at the remaining positions.

The vehicle control unit may further include a synchronization determination unit configured to periodically determine real-time synchronization under the same conditions between the detection level data and the second serial data of the second integrated data.

The vehicle control unit may further include a consistency determination unit configured to periodically determine the consistency between the second serial data of the second integrated data, determined as synchronized, and second serial data generated by the vehicle control unit.

The vehicle control unit may include a stop level determination unit configured to determine whether the detection level data received from the detection level data transmission unit is a stop level, a driving control unit configured to apply a driving control signal to the carriage when the detection level data is not a stop level, and a stop control unit configured to apply a stop control signal to the carriage when the detection level data is a stop level.

According to another embodiment of the present invention, there is provided a carriage driving method of a carriage driving system which includes a carriage configured to travel along a driving rail of a track, a driving direction detection unit formed on a part of the carriage and configured to detect a driving direction or surrounding objects, and a vehicle control unit formed on another part of the carriage and configured to control driving of the carriage. The carriage driving method includes: (a) at the driving direction detection unit, receiving area detection command data or command input/output data from the vehicle control unit; (b) at the driving direction detection unit, generating first serial data and integrating the area detection command data or command input/output data with the first serial data or sequentially transmitting them to the vehicle control unit; and (c) at the vehicle control unit, receiving first integrated data, in which the area detection command data or command input/output data and the first serial data are integrated or sequentially linked.

The carriage driving method may further include, after step (c): (d) at the vehicle control unit, periodically determining real-time synchronization under same conditions between the area detection command data or command input/output data and the first serial data of the first integrated data; (e) at the vehicle control unit, periodically determining the consistency between the first serial data of the first integrated data, determined as synchronized, and first serial data generated by the vehicle control unit; and (f) at the vehicle control unit, outputting an error signal to stop driving or enable taking follow-up actions if synchronization or consistency is determined to be inadequate.

The carriage driving method may further include, after step (f): (g) at the driving direction detection unit, transmitting detection level data detected by a sensor to the vehicle control unit; (h) at the driving direction detection unit, generating second serial data and integrating the detection level data and the second serial data or sequentially transmitting them to the vehicle control unit; and (i) at the vehicle control unit, receiving second integrated data in which the detection level data and the second serial data are integrated or sequentially linked.

The carriage driving method may further include, after step (i): (j) at the vehicle control unit, periodically determining real-time synchronization under the same conditions between the detection level data and the second serial data of the second integrated data; (k) at the vehicle control unit, periodically determining the consistency between the second serial data of the second integrated data, determined as synchronized, and second serial data generated by the vehicle control unit; and (l) at the vehicle control unit, outputting an error signal to stop driving or enable taking follow-up actions if synchronization or consistency is determined to be inadequate.

The carriage driving method may further include, after step (l): (m) at the vehicle control unit, determining whether received detection level data is a stop level; (n) applying a driving control signal to the carriage when the received detection level data is not a stop level; and (o) applying a stop control signal to the carriage when the detection level data is a stop level.

in step (c), the first integrated data may be a data set in which first serial data, located at one or more predetermined positions among the front, middle, or rear position of the entire data set, is integrated with command data located at the remaining positions, and in step (i), the second integrated data may be a data set in which second serial data, located at one or more predetermined positions as among the front, middle, or rear position of the entire data set, is integrated with detection level data located at the remaining positions.

According to still another embodiment of the present invention, a carriage driving system

includes: a carriage configured to travel along a driving rail of a track; a driving direction detection unit formed on a part of the carriage and configured to detect a driving direction or surrounding objects; and a vehicle control unit formed on another part of the carriage and configured to control driving of the carriage, wherein the driving direction detection unit includes at least one serial data generation unit configured to generate serial data, allowing the vehicle control unit to check in real time whether the driving direction detection unit is operating normally, the driving direction detection unit includes an area detection command data receiving unit configured to receive area detection command data or command input/output data from the vehicle control unit and a first serial data generation unit configured to generate first serial data and integrate the area detection command data or command input/output data with the first serial data, the vehicle control unit includes an area detection command data transmission unit configured to transmit the area detection command data or command input/output data to the area detection command data receiving unit, a first integrated data receiving unit configured to receive first integrated data in which the area detection command data or command input/output data and the first serial data are integrated or sequentially linked, a synchronization determination unit configured to periodically determine real-time synchronization under same conditions between the area detection command data or command input/output data and the first serial data of the first integrated data, a consistency determination unit configured to periodically determine consistency between the first serial data of the first integrated data, determined as synchronized, and first serial data generated by the vehicle control unit, and an error signal output unit configured to output an error signal to stop driving or enable taking follow-up actions when synchronization or consistency is determined to be inadequate, the driving direction detection unit includes a detection level data transmission unit configured to transmit detection level data detected by a sensor to the vehicle control unit and a second serial data generation unit configured to generate second serial data and integrate the detection level data with the second serial data or sequentially transmitting them to the vehicle control unit, and the vehicle control unit includes a second integrated data receiving unit configured to receive second integrated data in which the detection level data and the second serial data are integrated or sequentially linked, a synchronization determination unit configured to periodically determine real-time synchronization under same conditions between the detection level data and the second serial data of the second integrated data, a consistency determination unit configured to periodically determine consistency between the second serial data of the second integrated data, determined as synchronized, and second serial data generated by the vehicle control unit, a stop level determination unit configured to determine whether the detection level data received from the detection level data transmission unit is a stop level, a driving control unit configured to apply a driving control signal to the carriage when the detection level data is not a stop level, and a stop control unit configured to apply a stop control signal to the carriage when the detection level data is a stop level.

### BRIEF DESCRIPTION OF THE DRAWINGS

FIG. 1 is a schematic top view of a track layout of a carriage driving system according to some embodiments of the present invention.

FIG. 2 is a front view of a carriage of the carriage driving system of FIG. 1.

FIG. 3 is a side view of a carriage of the carriage driving system of FIG. 1.

FIG. 4 is a block diagram conceptually illustrating the carriage driving system of FIG. 1.

FIG. 5 is a diagram illustrating an example of first integrated data used in the carriage driving system of FIG. 4.

FIG. 6 is a diagram illustrating an example of second integrated data used in the carriage driving system of FIG. 4.

FIG. 7 is a flowchart illustrating a carriage driving method according to some embodiments of the present invention.

FIG. 8 is a flowchart illustrating a carriage driving method according to other embodiments of the present invention.

FIG. 9 is a flowchart illustrating a carriage driving method according to still other embodiments of the present invention.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

Hereinafter, various preferred embodiments of the present invention will be described in detail with reference to the accompanying drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. Moreover, in the drawing figures, the thickness or dimensions of layers are exaggerated for clarity and convenience of explanation.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components, and/or groups thereof, but do not preclude the presence or addition of one or more other features, integers, steps, operations, elements, components, and/or groups thereof.

Embodiments of the invention are described herein with reference to drawings that are schematic illustrations of idealized embodiments of the invention. As such, variations from the shapes of the drawings as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing.

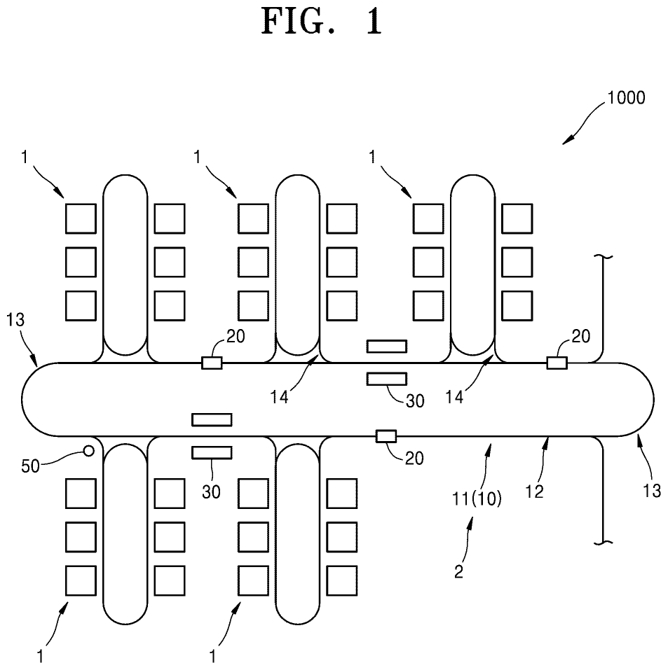

FIG. 1 is a schematic top view of a track layout of a carriage driving system 1000 according to some embodiments of the present invention.

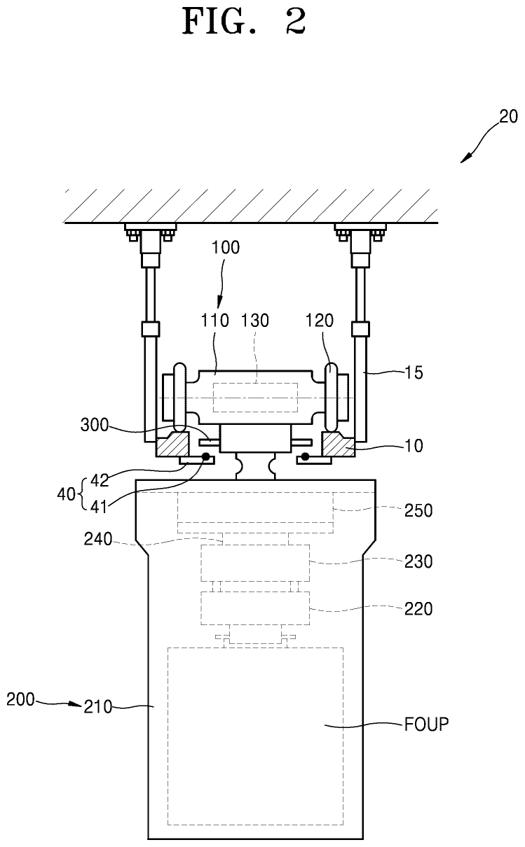

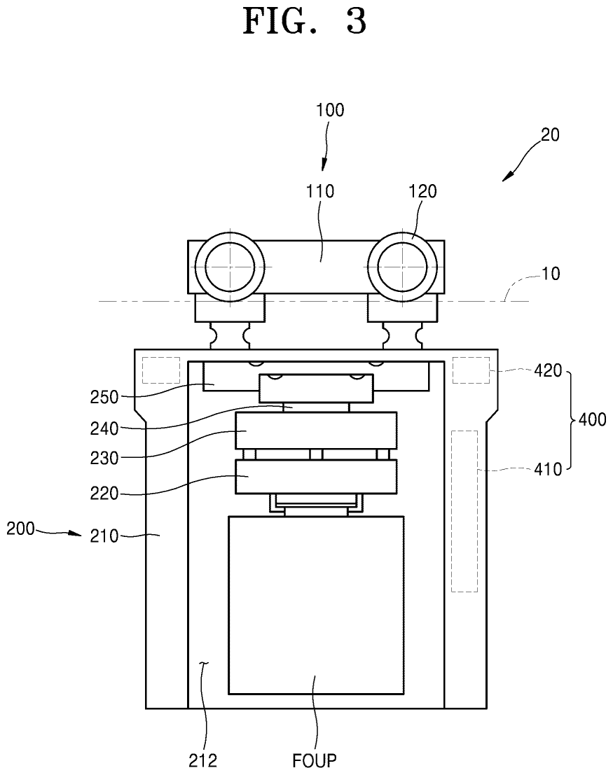

As illustrated in FIG. 1, reference numeral 1 denotes a plurality of pieces of semiconductor manufacturing equipment installed in a semiconductor manufacturing plant, and reference numeral 10 represents a track, i.e., a driving rail, that provides a transport path 11 for transporting an article, FOUP (see FIGS. 2 and 3), between the semiconductor manufacturing equipment 1.

Reference numeral 20 denotes a plurality of carriages that move along the transport path 11 to transport articles, and reference numeral 30 denotes one or more buffers that provide temporary storage space for the articles. The track, i.e., driving rail 10, is arranged on the ceiling side of the semiconductor manufacturing plant. The carriages 20 may transport articles directly from one piece of semiconductor manufacturing equipment 1 to another, or they may temporarily store the articles in the buffer 30 before transporting them to other equipment. The buffer 30 may be a side-rail buffer mounted at a side of the transport path 11, or an under-rail buffer mounted under the transport path 11.

The carriage driving system 1000 according to some embodiments of the present invention may include at least one carriage 20 that travels along the driving rail 10. The carriage driving system 1000 according to some embodiments of the present invention is configured in such a manner that the carriages 20 operate by receiving driving power from a power supply device through a power supply unit and a power receiving unit, and it may further include an integrated control unit to automatically operate the carriages 20. In addition, the carriage driving system 1000 may further include equipment such as a maintenance lifter, a vehicle lifter, or a test bench for the maintenance and repair of the carriages 20.

The transport path 11 may include one or more linear sections 12 with a linear line shape, one or more curved sections 13 with a curved line shape, and one or more joint section 14 for the branch and/or merging of paths, and a track control device 50 configured to control a driving direction of the carriage 20 may be installed in the joint section 14.

FIG. 2 is a front view of the carriage 20 of the carriage driving system 1000 of FIG. 1, and FIG. 3 is a side view of the carriage 20 of the carriage driving system 1000 of FIG. 1.

The driving rail 10 includes, for example, a pair of rail members that are spaced apart from each other in the left and right directions and are paired together, and is installed on the ceiling side of the semiconductor manufacturing plant by rail supports 15. The rail supports 15 may have lower ends supporting the pair of rail members and upper ends fixed to the ceiling of the semiconductor manufacturing plant. The pair of rail members may be formed to provide driving surfaces thereon.

The power supply unit 40 includes, for example, a power supply line 41 installed beneath the driving rail 10 along the transport path (11, see FIG. 1). A pair of power supply lines 41 are provided. The power supply lines 41 may be supported by line supports 42 positioned between the pair of rail members and mounted on the driving rail 10. The power supply lines 41 are electrically connected to a power supply device that provides driving power. For example, the power supply lines 41 may be installed only in the linear sections 12 of the transport path 11, and may not be installed in the curved sections 13 or the joint sections 14 of the transport path 11. As such, the transport path 11 may have power supply sections where the power supply lines 41 are mounted and no power supply sections where the power supply lines 41 are not mounted.

Each carriage 20 includes a vehicle 100 that travels along the driving rail 10, and a hoist device 200 that supports an article, such as an FOUP, beneath the vehicle 100. The hoist device 200 moves together with the vehicle 100 and supports the article.

The vehicle 100 comprises a chassis 110 and wheels 120. An axle extending in the lateral direction is mounted on the chassis 110. Multiple axles are provided and may be spaced apart from each other in the longitudinal direction. The wheels 120 are driving wheels that provide mobility to the chassis 110 so it can travel as guided by the driving rail 10. The wheels 120 are mounted at both ends of the axle and may roll by coming into contact with the driving surfaces of the pair of driving rails 10. The vehicle 100 further includes a wheel drive unit 130 that provides power to rotate the wheels 120. For example, the wheel drive unit 130 may be configured to rotate the axles.

The hoist device 200 includes a hoist housing 210. The hoist housing 210 is connected to the vehicle 100 beneath the driving rail 10. An upper part of the hoist housing 210 may be connected to a lower part of the chassis 110 through one or more connectors. The hoist housing 210 provides a storage space 212 in which the article is stored.

The hoist housing 210 is designed with a structure that is fully open on the left, right, and bottom sides, allowing the article to move left, right, and downward within the storage space 212.

In addition, the hoist device 200 includes a hand unit 220 for gripping or ungripping the article and a hand movement unit that moves the hand unit 220 between a first position and a second position. The first position is where the article gripped by the hand unit 220 is stored in the storage space 212 of the hoist housing 210, and the second position is outside the hoist housing 210 at a location away from the first position. The hoist device 200 includes a vertical drive unit 230, a rotary drive unit 240, and a horizontal drive unit 250 as the hand movement unit.

The hand unit 220 may include a hand that performs gripping and ungripping of the article, and a hand support that supports the hand. The vertical drive unit 230 moves the hand unit 220 in the vertical direction. The vertical drive unit 230 may move the hand unit 220 in the vertical direction by winding or unwinding at least one belt on a drum. The rotary drive unit 240 rotates the hand unit 220 about a vertical axis, while the horizontal drive unit 250 moves the hand unit 220 in the horizontal direction. For example, the hand unit 220 may be moved up and down by the vertical drive unit 230, the vertical drive unit 230 may be rotated about the vertical axis by the rotary drive unit 240, and the rotary drive unit 240 may moved in the horizontal direction by the horizontal drive unit 250, allowing the article gripped by the hand unit 220 to be moved in the vertical direction, rotated about the vertical axis, or moved in the horizontal direction.

The carriage 20 further includes a first power source device (main power source device 300) that receives power from the power supply line 41 in a non-contact manner and provides it to a vehicle body, and a second power source device (sub power source device, 400) that supplies power accumulated in a battery 410 to the vehicle body and shares power with neighboring vehicle bodies via a power-sharing module 420.

The first power source device 300 includes a power receiving unit provided below the vehicle 100 or above the hoist device 200 to face the power supply line 41. The power receiving unit may include a pickup coil and a rectifier. Since alternating current flows through the power supply line 41, the direction and intensity of the magnetic flux generated near the power supply line 41 constantly fluctuate. The pickup coil may generate an induced voltage by electromagnetic induction in response to these fluctuations in magnetic flux. Although the generated voltage is alternating current, it may be converted into direct current by the rectifier and supplied to the vehicle body.

The battery 410 may receive and store power from the first power source device 300 and supply the stored power to the vehicle body.

The power-sharing module 420 is electrically connected to the battery 410 to receive power from the battery 410 of another vehicle body or supply power to the battery 410 of another vehicle body. In other words, it may share battery power with another vehicle body.

The battery 410 and the power-sharing module 420 are provided at multiple positions within the vehicle body. As shown in FIG. 3, the battery 410 and the power-sharing module 420 may be mounted on the hoist device 200, which is structurally advantageous in terms of securing mounting space. Specifically, the battery 410 and the power-sharing module 420 may be embedded in the hoist housing 210. In this case, a plurality of power-sharing modules 420 may be provided to facilitate power sharing with a nearby vehicle.

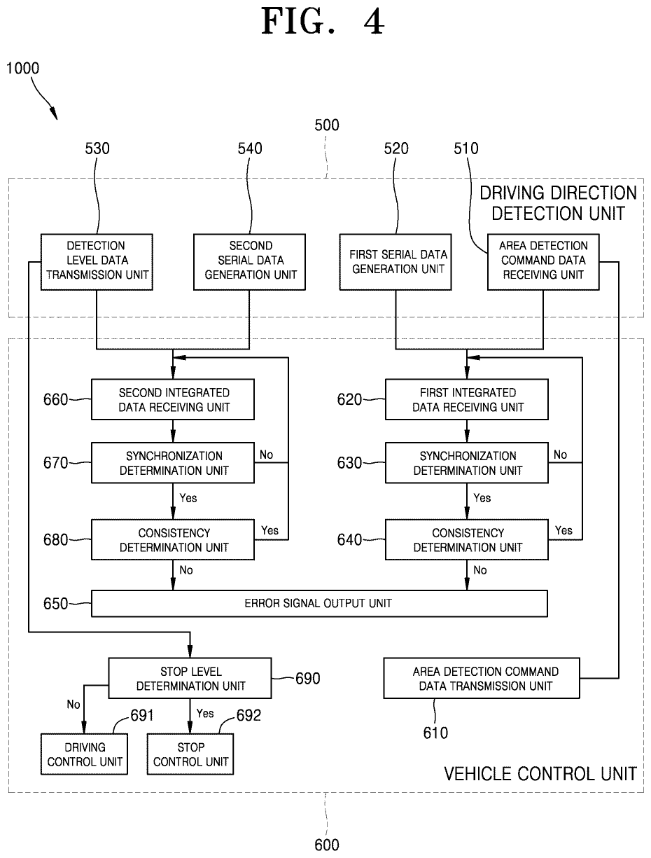

FIG. 4 is a block diagram conceptually illustrating the carriage driving system of FIG. 1.

As shown in FIGS. 1 to 4, the carriage driving system 1000 according to some embodiments of the present invention may include a driving direction detection unit 500 formed on a part of the carriage 20 that travels along the driving rail 10 of the track 2 to detect the driving direction or surrounding objects, and a vehicle control unit 600 formed on another part of the carriage 20 to control the driving of the carriage 20.

The driving direction detection unit 500 is installed on a part of the vehicle 100 or hoist device 200 shown in FIGS. 2 and 3 and may include various sensors such as detection switches, cameras, distance detection sensors, ultrasonic sensors, rail detection sensors, and surrounding object detection sensors to detect the driving direction of the vehicle 100, such as left turns, straight driving, or right turns, or to detect surrounding objects so as to prevent collisions.

The vehicle control unit 600, which may be installed on a part of the vehicle 100 or hoist device 200 shown in FIGS. 2 and 3, or may be installed on an external server that is connected and communicates with the carriage 20, may control the driving of the carriage through wired and/or wireless communication with the driving direction detection unit 500. It may include various electronic control devices, such as a microprocessor, a semiconductor chip, an integrated circuit, a central processing unit, an arithmetic unit, a computer, a server computer, a smart pad, a smartphone, a smart device, an electronic device, a program processing device capable of processing a series of programs, or a storage device where programs are stored.

The driving direction detection unit 500 may include at least one or more serial data generation units 520 and 540 that generate serial data, allowing the vehicle control unit 600 to check in real time whether the driving direction detection unit 500 is operating normally.

Serial data may refer to a data set which is a collection of data sequentially recorded over time and arranged in order, where only one piece of unique data is generated at a time. The serial data may be generated consecutively at regular intervals or as needed, with each one differing from the previous one.

More specifically, as shown in FIG. 4, the driving direction detection unit 500 may include an area detection command data receiving unit 510 that receives area detection command data or command input/output data from the vehicle control unit 600, a first serial data generation unit 520 that generates first serial data and integrates the area detection command data or command input/output data with the first serial data, a detection level data transmission unit 530 that transmits detection level data detected by a sensor to the vehicle control unit 600, and a second serial data generation unit 540 that generates second serial data and integrates the detection level data with the second serial data.

The area detection command data may include various forms and types of command information related to the driving direction that must be performed in order to reach a designated area, such as a command to make two left turns, a command to move forward once, and a command to make one right turn.

The detection level data may include various forms and types of actual detection information, which may be used to determine whether the commands are being properly executed in accordance with the command information. Specifically, the detection level data may include, for example, two left turn level detections, one forward movement level detection, and one right turn level detection, which indicate whether the vehicle has correctly followed the command information.

Therefore, the driving direction detection unit 500 may perform a series of processes including receiving the area detection command data or command input/output data from the vehicle control unit 600, generating the first serial data and integrating the area detection command data or command input/output data with the first serial data, transmitting the detection level data detected by a sensor to the vehicle control unit 600, generating the second serial data and integrating the detection level data with the second serial data.

The vehicle control unit 600, as shown in FIG. 4, may include, for example, an area detection command data transmission unit 610 that transmits area detection command data or command input/output data to the area detection command data receiving unit 510, and a first integrated data receiving unit 620 that receives first integrated data in which the area detection command data or command input/output data and the first serial data are integrated or sequentially linked.

Also, the vehicle control unit 600 may further include a synchronization determination unit 630 that periodically determines real-time synchronization under the same conditions between the area detection command data or command input/output data and the first serial data of the first integrated data D1. It may also include a consistency determination unit 640 that periodically determines the consistency between the first serial data of the first integrated data D1, determined as synchronized, and the first serial data generated by the vehicle control unit 600 or an external server. Additionally, the vehicle control unit 600 may further include an error signal output unit 650 that outputs an error signal to stop driving or enable taking follow-up actions if synchronization or consistency is determined to be inadequate.

Therefore, the vehicle control unit 600 may transmit the area detection command data or command input/output data to the area detection command data receiving unit 510 and receive the first integrated data, in which the area detection command data or command input/output data and the first serial data are integrated or sequentially linked, from the driving direction detection unit 500.

Additionally, the vehicle control unit 600 may automatically perform a series of processes including periodically determining real-time synchronization under the same conditions between the area detection command data or command input/output data and the first serial data of the first integrated data D1, periodically determining the consistency between the first serial data of the first integrated data D1, determined as synchronized, and the first serial data generated by the vehicle control unit 600 or an external server, and outputting an error signal to stop driving or enable taking follow-up actions, if synchronization or consistency is determined to be inadequate.

Thus, during the communication process of the area detection command data or command input/output data between the vehicle control unit 600 and the driving direction detection unit 500, the first serial data generation unit 520 installed in the driving direction detection unit 500 may enable the vehicle control unit 600 to detect in real time whether there is an abnormality in the driving direction detection unit 500. This allows the abnormal condition of the carriage 20 to be identified in advance, before a collision occurs, enabling quick follow-up actions to prevent collisions of the carriages 20 and avoid damage to semiconductor materials or parts. It also makes it easier to identify the cause of malfunctions, thereby reducing repair time and logistics interruptions, which can greatly improve productivity. Furthermore, the accuracy and reliability of operations may be significantly enhanced by periodically determining real-time synchronization of various data and verifying the consistency of the synchronized data.

Meanwhile, the vehicle control unit 600 may include a second integrated data receiving unit 660 that receives second integrated data D2 in which, for example, the detection level data and the second serial data are integrated or sequentially linked, a synchronization determination unit 670 that periodically determines real-time synchronization under the same conditions between the detection level data and the second serial data of the second integrated data D2, and a consistency determination unit 680 that periodically determines the consistency between the second serial data of the second integrated data D2, determined as synchronized, and second serial data generated by the vehicle control unit.

Meanwhile, the vehicle control unit 600 may perform a series of processes including receiving second integrated data D2 in which, for example, the detection level data and the second serial data are integrated or sequentially linked, periodically determining real-time synchronization under the same conditions between the detection level data and the second serial data of the second integrated data D2, and periodically determining the consistency between the second serial data of the second integrated data D2, determined as synchronized, and the second serial data generated by the vehicle control unit.

Thus, during the communication process of the detection data between the vehicle control unit 600 and the driving direction detection unit 500, the second serial data generation unit 540 installed in the driving direction detection unit 500 may enable the vehicle control unit 600 to detect in real time whether there is an abnormality in the driving direction detection unit 500. This allows the abnormal condition of the carriage 20 to be identified in advance, before a collision occurs, enabling quick follow-up actions to prevent collisions of the carriages 20 and avoid damage to semiconductor materials or parts. It also makes it easier to identify the cause of malfunctions, thereby reducing repair time and logistics interruptions, which can greatly improve productivity. Furthermore, the accuracy and reliability of operations may be significantly enhanced by periodically determining real-time synchronization of various data and verifying the consistency of the synchronized data.

Meanwhile, the vehicle control unit 600 may further include, for example, as shown in FIG. 4, a stop level determination unit 690 that determines whether the detection level data received from the detection level data transmission unit 530 is a stop level, a driving control unit 691 that applies a driving control signal to the carriage 20 if the detection level data is not a stop level, and a stop control unit 692 that applies a stop control signal to the carriage 20 if the detection level data is a stop level.

Therefore, the vehicle control unit 600 may automatically perform a series of processes to determine whether the detection level data received from the detection level data transmission unit 530 is a stop level, and, if the detection level data is not a stop level, apply a driving control signal to the carriage 20, or if the detection level data is a stop level, apply a stop control signal to the carriage 20.

Accordingly, according to the present invention, before a collision occurs between the carriages 20, it is possible to check in real-time for abnormal conditions of the carriages 20 by using the synchronization and consistency of serial data, and if an abnormality is detected, the vehicle may be stopped and follow-up actions can be taken promptly.

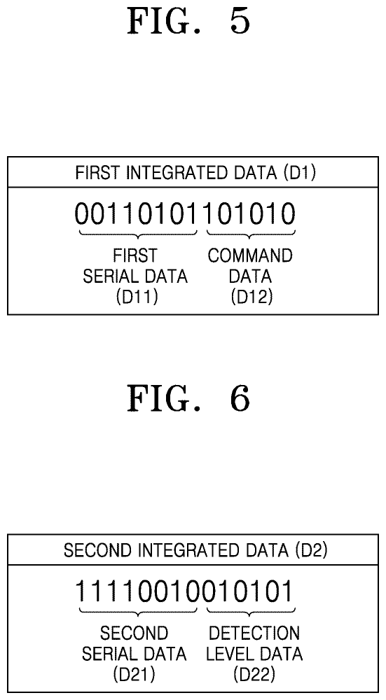

FIG. 5 is a diagram illustrating an example of the first integrated data DI used in the carriage driving system 1000 of FIG. 4, and FIG. 6 is a diagram illustrating an example of the second integrated data D2 used in the carriage driving system 1000 of FIG. 4.

The first integrated data DI may be, for example, as shown in FIG. 5, a data set in which first serial data D11, located at one or more predetermined positions among the front, middle, or rear position of the entire data set, is integrated with command data D12 located at the remaining positions.

Therefore, first by determining the synchronization and consistency of the first serial data D11 of the first integrated data D1, the reliability of the remaining command data D12 may be ensured only when the synchronization and consistency are determined to be in a normal state, thereby enabling normal communication.

The second integrated data D2 may be, for example, as shown in FIG. 6, a data set in which second serial data D21, located at one or more predetermined positions among the front, middle, or rear position of the entire data set, is integrated with detection level data D22 located at the remaining positions.

Therefore, first by determining the synchronization and consistency of the second serial data D21 of the second integrated data D2, the reliability of the remaining detection level data D22 may be ensured only when the synchronization and consistency are determined to be in a normal state, thereby enabling normal communication.

However, these first integrated data DI and second integrated data D2 are not necessarily limited to the drawings. For example, the second serial data D21 and the first serial data D11 may be made identical to facilitate synchronization and consistency determination, and various forms and types of data sets may be applied according to different protocols.

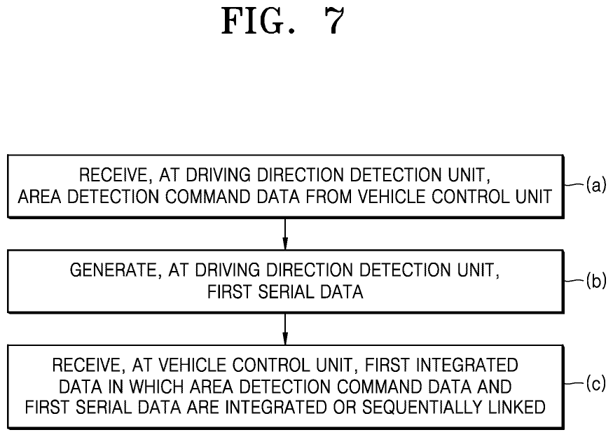

FIG. 7 is a flowchart illustrating a carriage driving method according to some embodiments of the present invention.

As shown in FIGS. 1 to 7, a carriage driving method according to some embodiments of the present invention may be a carriage driving method of the carriage driving system 1000, which includes the carriage 20 that travels along the driving rail 10 of the track 2, the driving direction detection unit 500 formed on a part of the carriage 20 to detect the driving direction or surrounding objects, and the vehicle control unit 600 formed on another part of the carriage 20 to control the driving of the carriage 20, and may include the steps of: (a) at the driving direction detection unit 500, receiving area detection command data or command input/output data from the vehicle control unit 600; (b) at the driving direction detection unit 500, generating first serial data and integrating area detection command data or command input/output data with the first serial data; and (c) at the vehicle control unit 600, receiving first integrated data DI in which the area detection command data or command input/output data and the first serial data are integrated or sequentially linked.

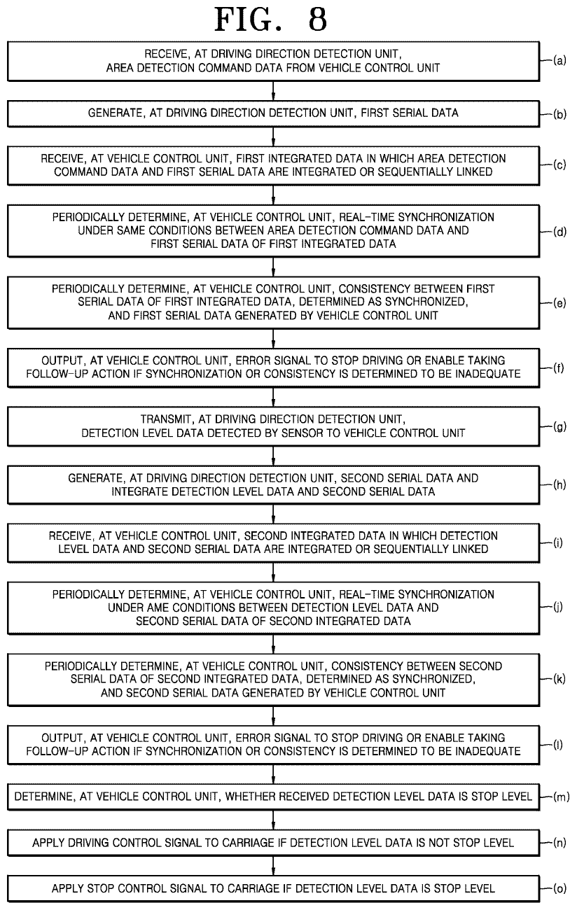

FIG. 8 is a flowchart illustrating a carriage driving method according to other embodiments of the present invention.

As shown in FIGS. 1 to 8, the carriage driving method according to other embodiments of the present invention may be a carriage driving method of the carriage driving system 1000, which includes the carriage 20 that travels along the driving rail 10 of the track 2, the driving direction detection unit 500 formed on a part of the carriage 20 to detect the driving direction or surrounding objects, and the vehicle control unit 600 formed on another part of the carriage 20 to control the driving of the carriage 20, and may include the steps of: (a) at the driving direction detection unit 500, receiving area detection command data or command input/output data from the vehicle control unit 600; (b) at the driving direction detection unit 500, generating first serial data and integrating the area detection command data or command input/output data with the first serial data; (c) at the vehicle control unit 600, receiving first integrated data D1, in which the area detection command data or command input/output data and the first serial data are integrated or sequentially linked; (d) at the vehicle control unit 600, periodically determining real-time synchronization under the same conditions between the area detection command data or command input/output data and the first serial data of the first integrated data; (e) at the vehicle control unit 600, periodically determining the consistency between the first serial data of the first integrated data D1, determined as synchronized, and first serial data generated by the vehicle control unit 600; (f) at the vehicle control unit 600, outputting an error signal to stop driving or enable taking follow-up actions if synchronization or consistency is determined to be inadequate; (g) at the driving direction detection unit 500, transmitting detection level data detected by a sensor to the vehicle control unit 600; (h) at the driving direction detection unit 500, generating second serial data and integrating the detection level data and the second serial data; (i) at the vehicle control unit 600, receiving second integrated data in which the detection level data and the second serial data are integrated or sequentially linked; (j) at the vehicle control unit 600, periodically determining real-time synchronization under the same conditions between the detection level data and the second serial data of the second integrated data D2; (k) at the vehicle control unit 600, periodically determining the consistency between the second serial data of the second integrated data D2, determined as synchronized, and second serial data generated by the vehicle control unit 600; (l) at the vehicle control unit 600, outputting an error signal to stop driving or enable taking follow-up actions if synchronization or consistency is determined to be inadequate; (m) at the vehicle control unit 600, determining whether received detection level data is a stop level; (n) applying a driving control signal to the carriage 20 if the received detection level data is not a stop level; and (o) applying a stop control signal to the carriage 20 if the detection level data is a stop level.

In step (c), the first integrated data D1 may be a data set in which first serial data D11, located at one or more predetermined positions among the front, middle, or rear position of the entire data set, is integrated with command data D12 located at the remaining positions. In step (i), the second integrated data D2 may be a data set in which second serial data D21, located at one or more predetermined positions among the front, middle, or rear position of the entire data set, is integrated with detection level data D22 located at the remaining positions.

However, these integrated data are not necessarily limited to the drawings, and various forms and types of data defined by a wide variety of protocols may be applied.

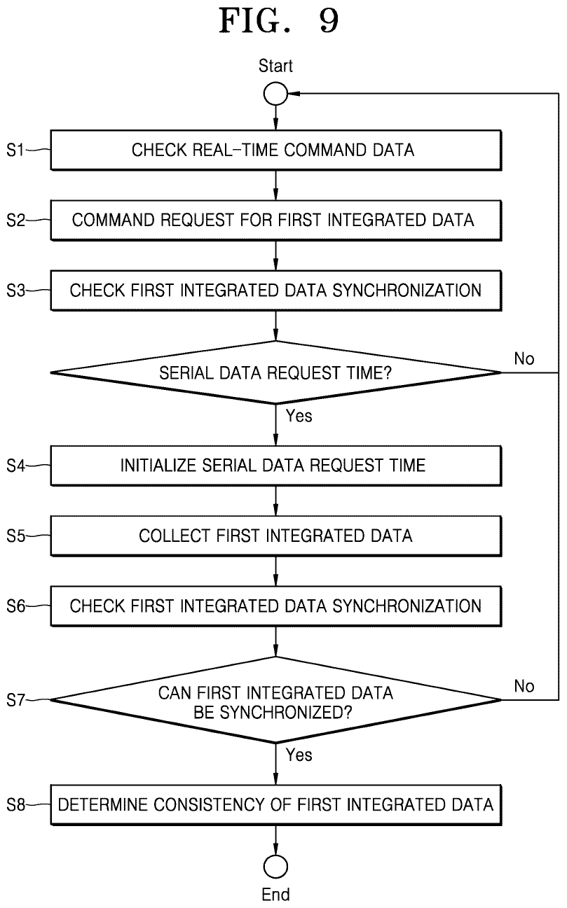

FIG. 9 is a flowchart illustrating a carriage driving method according to still other embodiments of the present invention.

As shown in FIGS. 1 to 9, the carriage driving method according to still other embodiments of the present invention begins with the vehicle control unit 600 or the driving direction detection unit 500 checking real-time command data S1, after which the vehicle control unit 600 may command a request for first integrated data from the driving direction detection unit 500 (S2). To check the synchronization of the first integrated data (S3), the serial data request time is checked and the serial data request time may be initialized (S4), thereby allowing the initialized first integrated data to be collected (S5).

Subsequently, the synchronization of the first integrated data may be checked (S6), and if the first integrated data can be synchronized (S7), the consistency of the synchronized first integrated data is determined (S8) to confirm whether it is in a normal state.

Here, the logic for checking the synchronization and consistency of the first integrated data may be applied in real time according to a fixed cycle, and this logic may be applied equally to the second integrated data.

According to various embodiments of the present invention, as described above, the serial data generation unit installed in the driving direction detection unit may enable the vehicle control unit to detect in real time whether there is an abnormality in the driving direction detection unit, which allows the abnormal condition of a carriage to be identified in advance, before a collision occurs, enabling quick follow-up actions to prevent collisions of the carriages and avoid damage to semiconductor materials or parts. It may also make it easier to identify the cause of malfunctions, thereby reducing repair time and logistics interruptions, which can greatly improve productivity. Furthermore, the accuracy and reliability of operations may be significantly enhanced by periodically determining real-time synchronization of various data and verifying the consistency of the synchronized data. However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

### REFERENCE NUMERALS

1: SEMICONDUCTOR MANUFACTURING EQUIPMENT
2: TRACK
10: DRIVING RAIL
20: CARRIAGE
30: BUFFER
40: POWER SUPPLY UNIT
50: TRACK CONTROL DEVICE
100: VEHICLE
200: HOIST DEVICE
300: FIRST POWER SOURCE UNIT
400: SECOND POWER SOURCE UNIT
500: DRIVING DIRECTION DETECTION UNIT
510: AREA DETECTION COMMAND DATA RECEIVING UNIT
520: FIRST SERIAL DATA GENERATION UNIT
530: DETECTION LEVEL DATA TRANSMISSION UNIT
540: SECOND SERIAL DATA GENERATION UNIT
600: VEHICLE CONTROL UNIT
610: AREA DETECTION COMMAND DATA TRANSMISSION UNIT
620: FIRST INTEGRATED DATA RECEIVING UNIT
D1: FIRST INTEGRATED DATA
D11: FIRST SERIAL DATA
D12: COMMAND DATA
630: SYNCHRONIZATION DETERMINATION UNIT
640: CONSISTENCY DETERMINATION UNIT
650: ERROR SIGNAL OUTPUT UNIT
660: SECOND INTEGRATED DATA RECEIVING UNIT
D2: SECOND INTEGRATED DATA
D21: SECOND SERIAL DATA
D22: DETECTION LEVEL DATA
670: SYNCHRONIZATION DETERMINATION UNIT
680: CONSISTENCY DETERMINATION UNIT
690: STOP LEVEL DETERMINATION UNIT
691: DRIVING CONTROL UNIT
692: STOP CONTROL UNIT
1000: CARRIAGE DRIVING SYSTEM

What is claimed is:

1. A carriage driving system comprising:
a carriage configured to travel along a driving rail of a track;
a driving direction detection unit formed on a part of the carriage and configured to detect a driving direction or surrounding objects; and
a vehicle control unit formed on another part of the carriage and configured to control driving of the carriage,
wherein the driving direction detection unit comprises at least one serial data generation unit configured to generate serial data so as to allow the vehicle control unit to check in real time whether the driving direction detection unit is operating normally.

2. The carriage driving system of claim 1, wherein the driving direction detection unit comprises
an area detection command data receiving unit configured to receive area detection command data or command input/output data from the vehicle control unit and
a first serial data generation unit configured to generate first serial data and integrate the area detection command data or command input/output data with the first serial data.

3. The carriage driving system of claim 2, wherein the vehicle control unit comprises
an area detection command data transmission unit configured to transmit the area detection command data or command input/output data to the area detection command data receiving unit and
a first integrated data receiving unit configured to receive first integrated data in which the area detection command data or command input/output data and the first serial data are integrated or sequentially linked.

4. The carriage driving system of claim 3, wherein the first integrated data is a data set in which first serial data, located at one or more predetermined positions among a front, middle, or rear position of the entire data set, is integrated with command data located at remaining positions.

5. The carriage driving system of claim 3, wherein the vehicle control unit further comprises a synchronization determination unit configured to periodically determine real-time synchronization under same conditions between the area detection command data or command input/output data and the first serial data of the first integrated data.

6. The carriage driving system of claim 5, wherein the vehicle control unit further comprises a consistency determination unit configured to periodically determine consistency between the first serial data of the first integrated data, determined as synchronized, and first serial data generated by the vehicle control unit or an external server.

7. The carriage driving system of claim 6, wherein the vehicle control unit further comprises an error signal output unit configured to output an error signal to stop driving or enable taking follow-up actions when synchronization or consistency is determined to be inadequate.

8. The carriage driving system of claim 1, wherein the driving direction detection unit comprises
a detection level data transmission unit configured to transmit detection level data detected by a sensor to the vehicle control unit and
a second serial data generation unit configured to generate second serial data and integrate the detection level data with the second serial data.

9. The carriage driving system of claim 8, wherein the vehicle control unit comprises a second integrated data receiving unit configured to receive second integrated data in which the detection level data and the second serial data are integrated or sequentially linked.

10. The carriage driving system of claim 9, wherein the second integrated data is a data set in which second serial data, located at one or more predetermined positions among a front, middle, or rear position of the entire data set, is integrated with detection level data located at remaining positions.

11. The carriage driving system of claim 9, wherein the vehicle control unit further comprises a synchronization determination unit configured to periodically determine real-time synchronization under same conditions between the detection level data and the second serial data of the second integrated data.

12. The carriage driving system of claim 11, wherein the vehicle control unit further comprises a consistency determination unit configured to periodically determine consistency between the second serial data of the second integrated data, determined as synchronized, and second serial data generated by the vehicle control unit.

13. The carriage driving system of claim 12, wherein the vehicle control unit comprises
a stop level determination unit configured to determine whether the detection level data received from the detection level data transmission unit is a stop level,
a driving control unit configured to apply a driving control signal to the carriage when the detection level data is not a stop level, and
a stop control unit configured to apply a stop control signal to the carriage when the detection level data is a stop level.

14. A carriage driving method of a carriage driving system which comprises a carriage configured to travel along a driving rail of a track, a driving direction detection unit formed on a part of the carriage and configured to detect a driving direction or surrounding objects, and a vehicle control unit formed on another part of the carriage and configured to control driving of the carriage, the carriage driving method comprising:
(a) at the driving direction detection unit, receiving area detection command data or command input/output data from the vehicle control unit;
(b) at the driving direction detection unit, generating first serial data and integrating the area detection command data or command input/output data with the first serial data; and
(c) at the vehicle control unit, receiving first integrated data, in which the area detection command data or command input/output data and the first serial data are integrated or sequentially linked.

15. The carriage driving method of claim 14, further comprising, after step (c):
(d) at the vehicle control unit, periodically determining real-time synchronization under same conditions between the area detection command data or command input/output data and the first serial data of the first integrated data;
(e) at the vehicle control unit, periodically determining consistency between the first serial data of the first integrated data, determined as synchronized, and first serial data generated by the vehicle control unit; and
(f) at the vehicle control unit, outputting an error signal to stop driving or enable taking follow-up actions if synchronization or consistency is determined to be inadequate.

16. The carriage driving method of claim 15, further comprising, after step (f):
(g) at the driving direction detection unit, transmitting detection level data detected by a sensor to the vehicle control unit;
(h) at the driving direction detection unit, generating second serial data and integrating the detection level data and the second serial data; and
(i) at the vehicle control unit, receiving second integrated data in which the detection level data and the second serial data are integrated or sequentially linked.

17. The carriage driving method of claim 16, further comprising, after step (i):
(j) at the vehicle control unit, periodically determining real-time synchronization under same conditions between the detection level data and the second serial data of the second integrated data;
(k) at the vehicle control unit, periodically determining consistency between the second serial data of the second integrated data, determined as synchronized, and second serial data generated by the vehicle control unit; and
(l) at the vehicle control unit, outputting an error signal to stop driving or enable taking follow-up actions if synchronization or consistency is determined to be inadequate.

18. The carriage driving method of claim 17, further comprising, after step (1):
(m) at the vehicle control unit, determining whether received detection level data is a stop level;
(n) applying a driving control signal to the carriage when the received detection level data is not a stop level; and
(o) applying a stop control signal to the carriage when the detection level data is a stop level.

19. The carriage driving method of claim 18, wherein in step (c), the first integrated data is a data set in which first serial data, located at one or more predetermined positions among a front, middle, or rear position of the entire data set, is integrated with command data located at remaining positions, and
in step (i), the second integrated data is a data set in which second serial data, located at one or more predetermined positions among a front, middle, or rear position of the entire data set, is integrated with detection level data located at remaining positions.

20. A carriage driving system comprising:
a carriage configured to travel along a driving rail of a track;
a driving direction detection unit formed on a part of the carriage and configured to detect a driving direction or surrounding objects; and
a vehicle control unit formed on another part of the carriage and configured to control driving of the carriage,
wherein the driving direction detection unit comprises at least one serial data generation unit configured to generate serial data, allowing the vehicle control unit to check in real time whether the driving direction detection unit is operating normally, and
the driving direction detection unit comprises
an area detection command data receiving unit configured to receive area detection command data or command input/output data from the vehicle control unit and
a first serial data generation unit configured to generate first serial data and integrate the area detection command data or command input/output data with the first serial data,
the vehicle control unit comprises
an area detection command data transmission unit configured to transmit the area detection command data or command input/output data to the area detection command data receiving unit,
a first integrated data receiving unit configured to receive first integrated data in which the area detection command data or command input/output data and the first serial data are integrated or sequentially linked,
a synchronization determination unit configured to periodically determine real-time synchronization under same conditions between the area detection command data or command input/output data and the first serial data of the first integrated data,
a consistency determination unit configured to periodically determine consistency between the first serial data of the first integrated data, determined as synchronized, and first serial data generated by the vehicle control unit, and
an error signal output unit configured to output an error signal to stop driving or enable taking follow-up actions when synchronization or consistency is determined to be inadequate,
the driving direction detection unit comprises
a detection level data transmission unit configured to transmit detection level data detected by a sensor to the vehicle control unit and
a second serial data generation unit configured to generate second serial data and integrate the detection level data with the second serial data, and
the vehicle control unit comprises
a second integrated data receiving unit configured to receive second integrated data in which the detection level data and the second serial data are integrated or sequentially linked,
a synchronization determination unit configured to periodically determine real-time synchronization under same conditions between the detection level data and the second serial data of the second integrated data,
a consistency determination unit configured to periodically determine consistency between the second serial data of the second integrated data, determined as synchronized, and second serial data generated by the vehicle control unit,
a stop level determination unit configured to determine whether the detection level data received from the detection level data transmission unit is a stop level,
a driving control unit configured to apply a driving control signal to the carriage when the detection level data is not a stop level, and
a stop control unit configured to apply a stop control signal to the carriage when the detection level data is a stop level.
